(19) United States
(12) Patent Application Publication
(10) Pub. No.: US 2026/0020421 A1
(43) Pub. Date: Jan. 15, 2026

(54) DISPLAY DEVICE AND MANUFACTURING METHOD THEREOF

(71) Applicant: AUO Corporation, Hsinchu City (TW)

(72) Inventor: Ming-Kuei Hsu, Hsinchu City (TW)

(21) Appl. No.: 18/965,185

(22) Filed: Dec. 2, 2024

(30) Foreign Application Priority Data
Jul. 9, 2024 (TW) 113125666

(51) Int. Cl. H10H 29/80

(52) U.S. Cl. CPC H10H 29/942

(57) ABSTRACT

A display device includes two transparent display units and a detachable transparent coupler. Each transparent display unit includes a first substrate, a second substrate and a display component disposed between the first substrate and the second substrate. The detachable transparent coupler is assembled between the two transparent display units. At a first side of the display device, a portion of the detachable transparent coupler protrudes from at least one of the first substrate and the second substrate of one of the two transparent display units.

### CROSS-REFERENCE TO RELATED PATENT APPLICATION

This non-provisional application claims priority to and the benefit of, pursuant to 35 U.S.C. § 119(a), patent application Serial No. 113125666 filed in Taiwan on Jul. 9, 2024. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to a display device and a manufacturing thereof, and in particular to a splicing display device and a manufacturing method thereof.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Conventionally, transparent display modules typically use a three-sided frameless design to achieve good transparency. However, in the case where such display modules are applied with splicing technology to form a large-sized display device, if a mechanism for splicing is disposed on the back of each display module, it may easily cause visual gaps, thus reducing the display quality. When the display modules are spliced using colloidal adhesive, the gaps may be too small, which hinders the flow of the adhesive and leads to the formation of air bubbles, thus causing poor filling and reducing manufacturing yield. Moreover, when reworking is required, the display device spliced using the colloidal adhesive requires extensive removal of the adhesive, such that the display modules are difficult to disassemble, which may even possibly damage the display modules.

### SUMMARY

One objective of the present disclosure is to provide a display device, in which a plurality of display units are assembled by a detachable coupler, thus effectively improving the convenience of splicing and detaching of the display device.

Another objective of the present disclosure is to provide a display device, in which a plurality of display units are assembled by a detachable coupler, thus effectively controlling the step misalignment of the display units and enhancing display quality.

In one embodiment of the present disclosure, a display device includes two transparent display units and a detachable transparent coupler. Each transparent display unit includes a first substrate, a second substrate and a display component disposed between the first substrate and the second substrate. The detachable transparent coupler is assembled between the two transparent display units. At a first side of the display device, a portion of the detachable transparent coupler protrudes from at least one of the first substrate and the second substrate of one of the two transparent display units.

In one embodiment, the display device further includes a colloidal adhesive disposed along edges of the two transparent display units, and the colloidal adhesive is not disposed at the first side of the display device.

In one embodiment, at a second side of the display device opposite to the first side, the detachable transparent coupler is recessed inward relative to the two transparent display units to form an adhesive space between the two transparent display units and the detachable transparent coupler, and the adhesive space is filled with the colloidal adhesive.

In one embodiment, the colloidal adhesive is located between the first substrate and the second substrate of each of the two transparent display units.

In one embodiment, at the first side of the display device, the first substrate of the one of the two transparent display units is recessed relative to the second substrate thereof, and the portion of the detachable transparent coupler protrudes to the recessed first substrate.

In one embodiment, the detachable transparent coupler has a positioning portion, the positioning portion is disposed on the portion of the detachable transparent coupler and protrudes from the detachable transparent coupler to contact a side edge of the at least one of the first substrate and the second substrate of the one of the two transparent display units.

In one embodiment, the detachable transparent coupler has a position limiting portion, the position limiting portion is disposed along a length direction of the detachable transparent coupler and protrudes from the detachable transparent coupler, and adjacent side edges of the two transparent display units respectively contact two opposite sides of the position limiting portion.

In one embodiment, transparency of the detachable transparent coupler is 80% or higher.

In one embodiment, reflectivity of the detachable transparent coupler is 5% or less.

In one embodiment, the display device further includes a base, where the two transparent display units and the detachable transparent coupler are disposed at a side of the base, and the portion of the detachable transparent coupler is adjacent to the base.

In one embodiment, the display device further includes a circuit board disposed in the base and electrically connected to the two transparent display units.

In another embodiment of the present disclosure, a manufacturing method of a display device includes: providing two transparent display units, wherein each of the transparent display units comprises a first substrate, a second substrate and a display component disposed between the first substrate and the second substrate; and assembling a detachable transparent coupler between the two transparent display units, such that at a first side of the display device, a portion of the detachable transparent coupler protrudes from at least one of the first substrate and the second substrate of one of the two transparent display units.

In one embodiment, the manufacturing method further includes: disposing a colloidal adhesive along edges of the two transparent display units, wherein the colloidal adhesive is not disposed at the first side of the display device.

In one embodiment, the step of assembling the detachable transparent coupler between the two transparent display units includes: at a second side of the display device opposite to the first side, recessing the detachable transparent coupler inward relative to the two transparent display units to form an adhesive space between the two transparent display units and the detachable transparent coupler; and the step of disposing the colloidal adhesive includes: disposing the colloidal adhesive in the adhesive space.

In one embodiment, the step of assembling the detachable transparent coupler between the two transparent display units includes: disposing one of the two transparent display units on the base; inserting a portion of the detachable transparent coupler into a side of the one of the two transparent display units; and disposing the other of the two transparent display units on the base, and inserting another portion of the detachable transparent coupler into a side of the other of the two transparent display units.

In one embodiment, the manufacturing method further includes: disposing a circuit board in the base, such that the circuit board is electrically connected to the two transparent display units.

In one embodiment, the manufacturing method further includes a reworking step. The reworking step includes: at the second side of the display device, removing a portion of the colloidal adhesive to at least expose the adhesive space; disassembling one of the two transparent display units to be reworked from the detachable transparent coupler; assembling a replacement transparent display unit in the detachable transparent coupler; and coating a reworking colloidal adhesive along edges of the replacement transparent display unit, wherein the reworking colloidal adhesive is filled in the adhesive space and is connected to an unremoved portion of the colloidal adhesive.

Compared to the related art, in the display device and the manufacturing method thereof according to the present disclosure, the transparent display units are assembled by the detachable coupler, thus effectively improving the convenience of splicing and detaching of the display device. Moreover, in the display device and the manufacturing method thereof according to the present disclosure, the transparent display units are assembled by the detachable coupler, thus effectively reducing the colloidal adhesive used for adhering between the transparent display units, enhancing the convenience of the reworking operation and reducing the possibility of damaging the transparent display units.

These and other aspects of the present disclosure will become apparent from the following description of the embodiment taken in conjunction with the following drawings, detailed description and the claims.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1A is a disassembled perspective schematic view of a display device according to one embodiment of the present disclosure.

FIG. 1B is an assembled perspective schematic view of the display device of FIG. 1A.

FIG. 1C is a top schematic view of a second side of the display device of FIG. 1B.

FIG. 2 is a partial plain schematic view of a second side of a display device according to one embodiment of the present disclosure.

FIGS. 3A to 3E are schematic view of a manufacturing method of a display device according to one embodiment of the present disclosure.

FIGS. 4A to 4C are schematic views of a positioning portion of a detachable transparent coupler according to different embodiments of the present disclosure.

FIGS. 5A to 5D are partial plain schematic views of a display device in a reworking operation according to one embodiment of the present disclosure.

### DETAILED DESCRIPTION

In the accompanying drawings, to clearly show the components, the thicknesses of the layers, films, panels and areas, etc. are enlarged. In the disclosure, identical drawing references indicates identical components. It should be understood that components such as the layers, films, panels and areas, etc., are referred to as being “on” or “connected to” another component, they may be on or connected to another component directly, or an intermediate component may exist therebetween. To the contrary, when a component is referred to as being “directly on” or “directly connected to” another component, there is no intermediate component therebetween. As used herein, being “connected” may refer to physical connection or electrical connection. Further, being “electrically connected” or “coupled” refers to the case where other components may exist between the two components.

It should be understood that terms such as “first”, “second”, and “third” are used to describe various elements, components, regions, layers and/or portions herein. However, these elements, components, regions, layers and/or parts should not be limited by these terms. These words are only used for distinguishing between an element, a component, a region, a layer and/or a part from another element, component, region, layer and/or portion. Therefore, a first “element”, “component”, “region”, “layer” and/or “portion” hereinafter may also be referred to as a second “element”, “component”, “region”, “layer” and/or “portion” without departing from the concept of the present disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom”, “upper” or “top”, and “left” and “right”, may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper”, depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terms “about”, “approximately”, “essentially” or “substantially” as used herein shall cover the values described, and cover an average value of an acceptable deviation range of the specific values ascertained by one of ordinary skill in the art, where the deviation range may be determined by the measurement described and specific quantities of errors related to the measurement (that is, the limitations of the measuring system). For example, the term “about” represents within one or more standard deviations of a given value of range, such as within ±30 percent, within ±20 percent, within ±15 percent, within ±10 percent or within ±5 percent. Moreover, the terms “about”, “approximately”, “essentially” or “substantially” as used herein may selectively refer to a more acceptable deviation range or the standard deviation based on the optical characteristics, etching characteristics or other characteristics, without applying one standard deviation to all characteristics.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Herein, exemplary embodiments are described with reference to sectional views of schematic diagrams of ideal embodiments. Therefore, changes of shapes in the drawings that are used as results of manufacturing technology, tolerances and/or the like may be expected. Therefore, herein, the embodiments should not be explained to be limited to particular shapes of regions herein, but instead, comprise shape deviations caused by manufacturing and the like. For example, regions that are shown or described to be flat may usually have rough and/or nonlinear features. In addition, a shown acute angle may be rounded. Therefore, regions in the drawings are essentially schematic, and shapes of the regions are not intended to show precise shapes of the regions and are not intended to limit the scope of the claims.

The present disclosure is related to a display device. The display device according to the present disclosure is a spliced display device having a larger-sized display surface by the splicing technology. The display device of the present disclosure will now be described in details hereinafter with reference to the accompanying drawings.

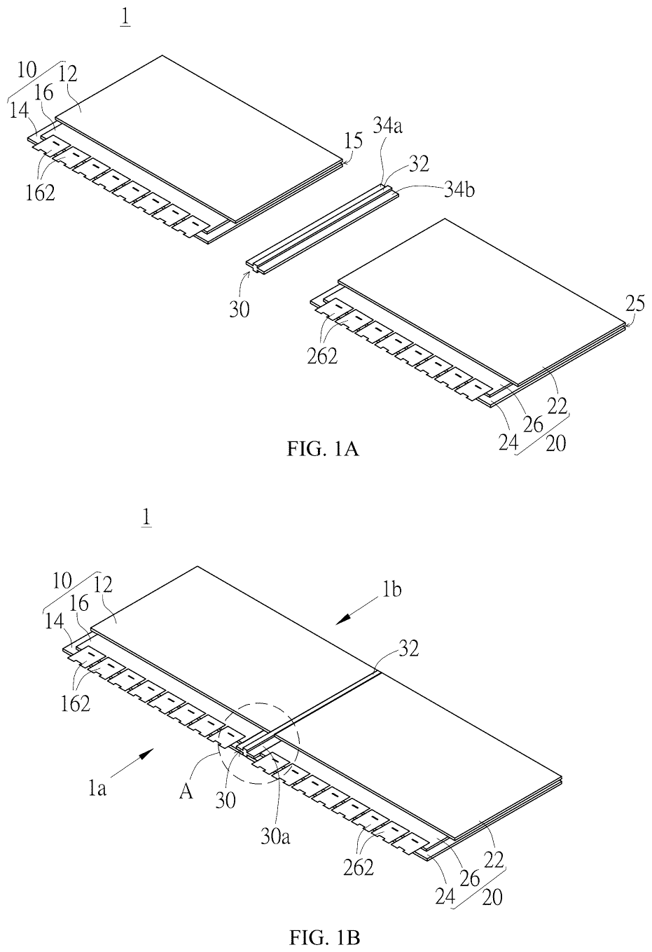

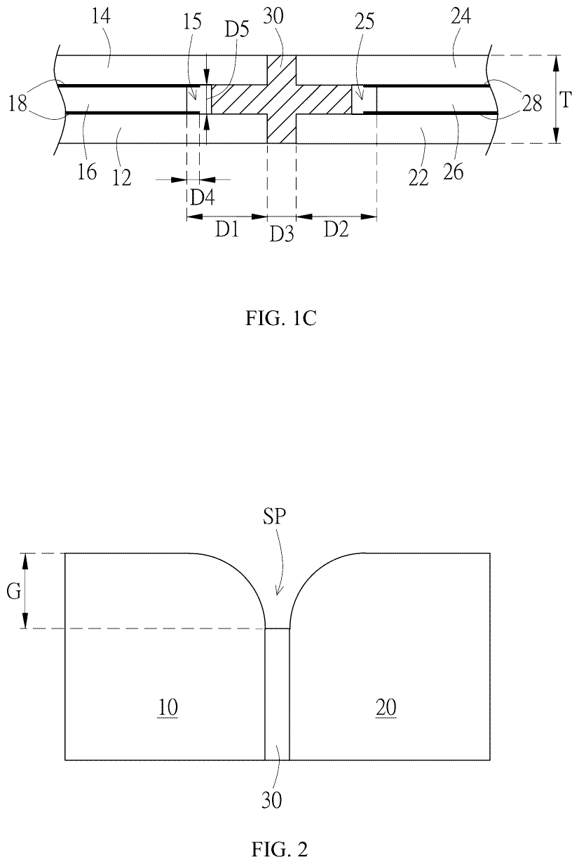

Referring to FIGS. 1A to 1C, FIG. 1A is a disassembled perspective schematic view of a display device 1 according to one embodiment of the present disclosure. FIG. 1B is an assembled perspective schematic view of the display device 1 of FIG. 1A. FIG. 1C is a top schematic view of a second side 1b of the display device 1 of FIG. 1B. As shown in FIGS. 1A to 1C, the display device 1 includes two transparent display units 10 and 20 and a detachable transparent coupler 30. Each transparent display unit 10, 20 includes a first substrate 12, 22, a second substrate 14, 24, and a display component 16, 26 disposed between the first substrate 12, 22 and the second substrate 14, 24. The detachable transparent coupler 30 is assembled between the two transparent display units 10 and 20. At a first side 1a of the display device 1, a portion 30a of the detachable transparent coupler 30 protrudes from at least one of the first substrate 12, 22 and the second substrate 14, 24 of one of the two transparent display units 10 and 20.

Specifically, the display device 1 has the first side 1a and a second side 1b opposite to the first side 1a. For example, the first side 1a and the second side 1b of the display device 1 are respectively an upper side and a lower side of the display device 1 in a vertical direction. The two transparent display units 10 and 20 are disposed side-by-side along a horizontal direction of the display device 1, such that the display surfaces of the two transparent display units 10 and 20 face the same direction. The detachable transparent coupler 30 is assembled to adjacent side edges of the two transparent display units 10 and 20 along the vertical direction of the display device 1.

The transparent display unit 10 includes a first substrate 12, a second substrate 14 and a display component 16 disposed between the first substrate 12 and the second substrate 14. Similarly, the transparent display unit 20 includes a first substrate 22, a second substrate 24 and a display component 26 disposed between the first substrate 22 and the second substrate 24. In the present embodiment, the transparent display unit 10 and the transparent display unit 20 preferably have identical structures, without being limited thereto. In other embodiments, the transparent display unit 10 and the transparent display unit 20 may have different structures. According to actual applications, any suitable transparent display unit may be used as the transparent display unit 10 and the transparent display unit 20 of the display device 1.

The first substrates 12 and 22 and the second substrates 14 and 24 of the transparent display units 10 and 20 are preferably transparent substrates, and the materials thereof may include, for example, glass, polymers, quartz, etc., for protecting and supporting the display components 16 and 26. In one embodiment, the display components 16 and 26 may be formed by a plurality of light emitting components and a circuit structure. The light emitting components are preferably disposed in an array, and the circuit structure includes a plurality of scan lines and a plurality of data lines for driving the light emitting components, thus forming a plurality of pixel units. The light emitting components may include light emitting diodes (e.g., micro LEDs), without being limited thereto. Moreover, as shown in FIG. 1C, the display component 16 may be adhered and fixed between the first substrate 12 and the second substrate 14 by an optical adhesive 18 to form the display unit 10, and the display component 26 may be adhered and fixed between the first substrate 22 and the second substrate 24 by an optical adhesive 28 to form the display unit 20.

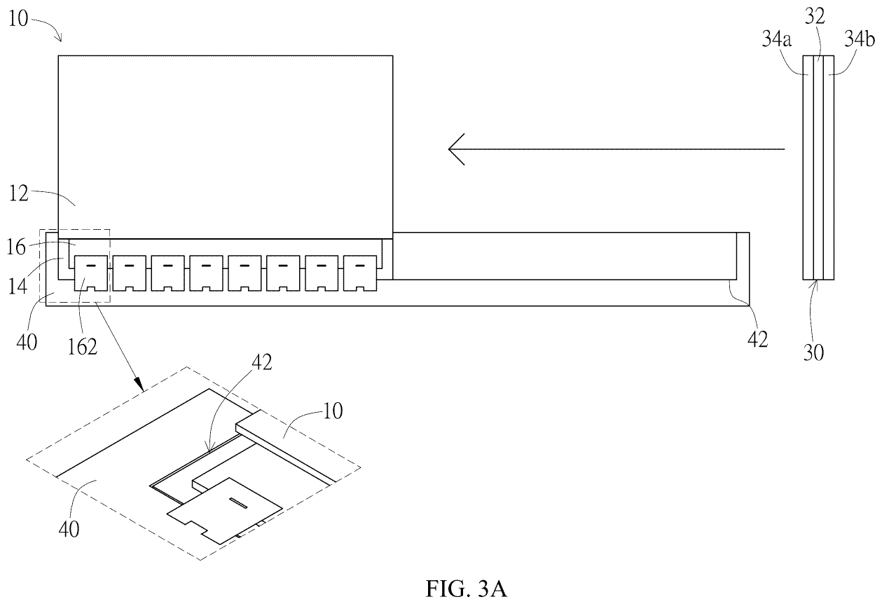

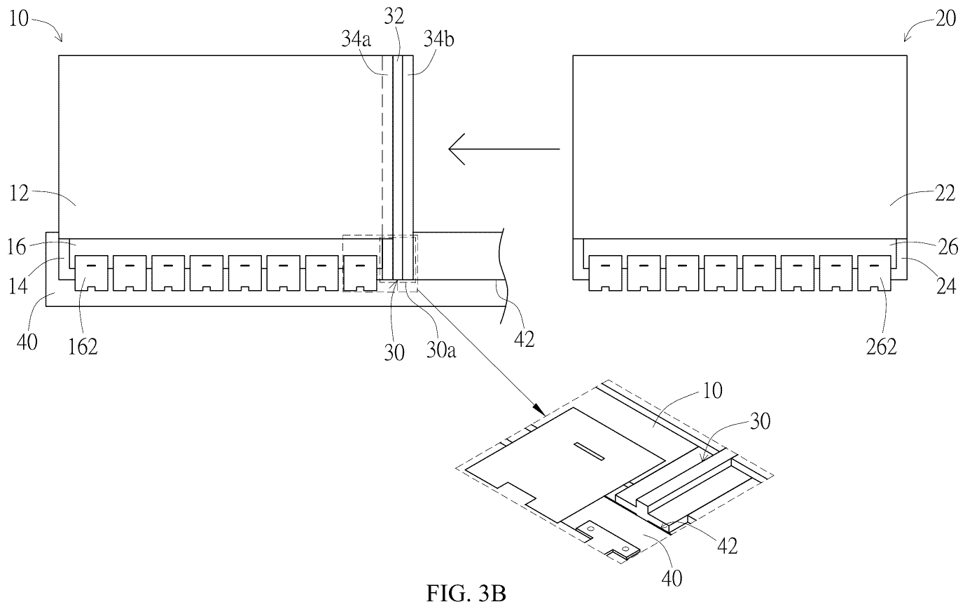

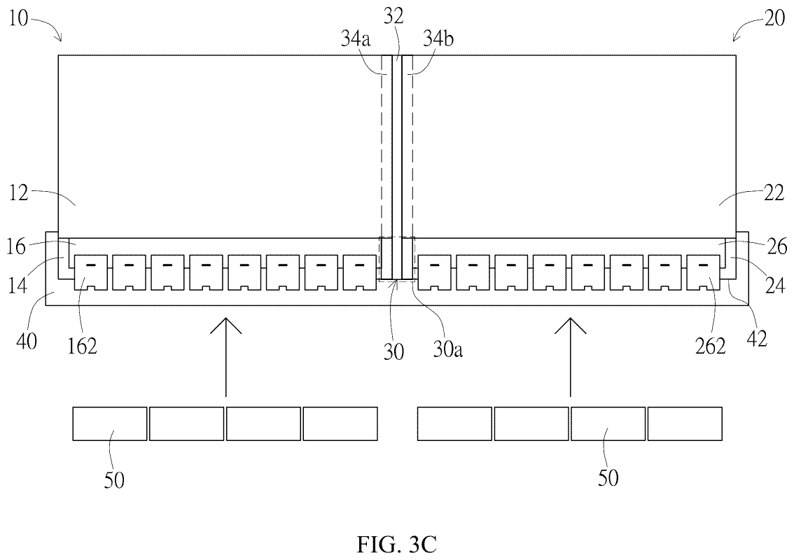

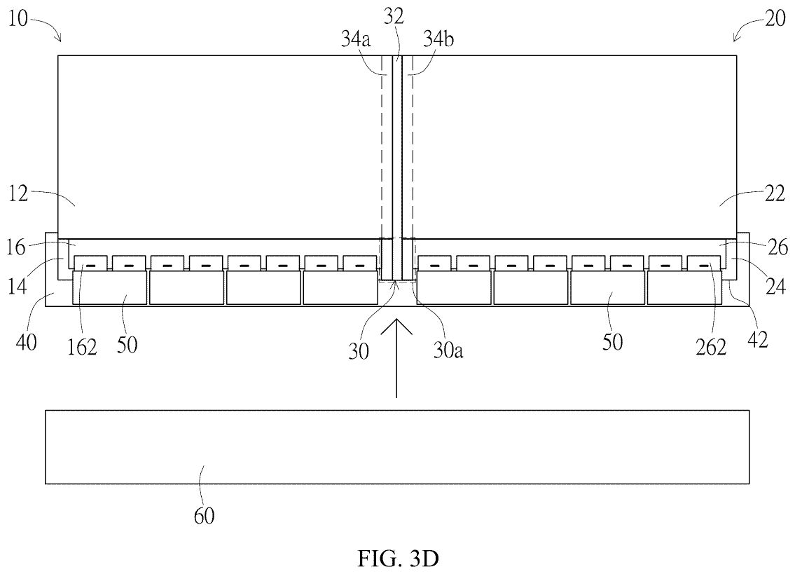

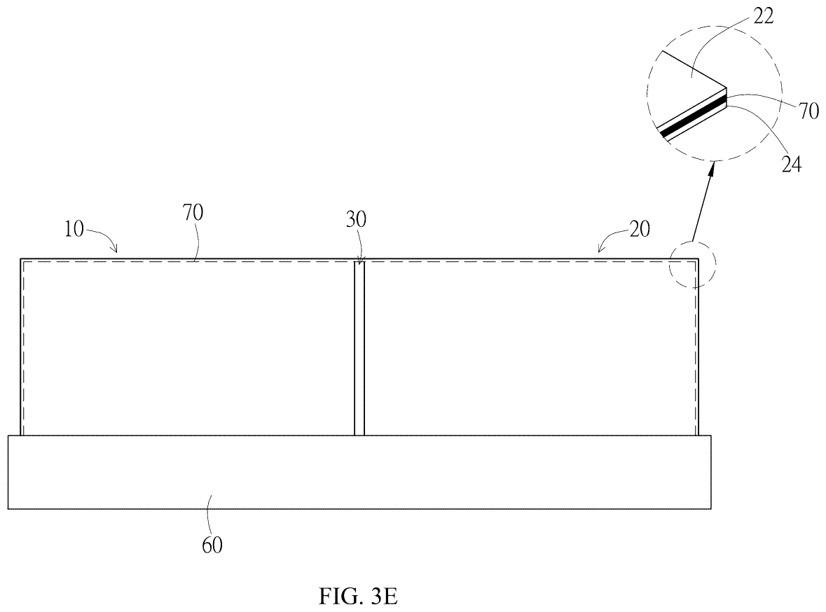

In addition, in one embodiment, at the first side 1a of the display device 1, the first substrate 12, 22 of one of the two transparent display units 10 and 20 is recessed relative to the second substrate 14, 24 thereof. As shown in FIGS. 1A and 1B, at the second side 1b of the display device 1, the edge of the first substrate 12 of the transparent display unit 10 is preferably aligned to the edge of the second substrate 14 thereof, and at the first side 1a of the display device 1, the first substrate 12 of the transparent display unit 10 is recessed relative to the second substrate 14 thereof, thus exposing the electrical connecting portion 162 of the display component 16. Similarly, at the second side 1b of the display device 1, the edge of the first substrate 22 of the transparent display unit 20 is preferably aligned to the edge of the second substrate 24 thereof, and at the first side 1a of the display device 1, the first substrate 22 of the transparent display unit 20 is recessed relative to the second substrate 24 thereof, thus exposing the electrical connecting portion 262 of the display component 26. Specifically, the dimension of the second substrate 14, 24 is preferably greater than that of the first substrate 12, 22, such that the first substrate 12, 22 at the first side 1a of the display device 1 does not fully cover the second substrate 14, 24, thereby exposing the electrical connecting portion 162, 262 of the display component 16, 26, which helps the subsequent electrical connection to the circuit board 50 (shown in FIG. 3D and described later in details) of the display device 1.

Moreover, as shown in FIG. 1B, since the first substrate 12 of the transparent display unit 10 is recessed relative to the second substrate 14 thereof, a portion 30a of the detachable transparent coupler 30 protrudes out of the recessed first substrate 12, 22, without being limited thereto. In another embodiment, the first substrate 12, 22 and the second substrate 14, 24 may have an identical dimension. For example, the edges of the first substrate 12, 22 and the edges of the second substrate 14, 24 may be aligned at the first side 1a and the second side 1b of the display device 1, such that the portion 30a of the detachable transparent coupler 30 protrudes out of the first substrate 12, 22 and the second substrate 14, 24 simultaneously. In one embodiment, a length of the portion 30a of the detachable transparent coupler 30 protruding out of the first substrate 12, 22 is preferably about 5.0 mm, without being limited thereto. According to actual applications, the length of the portion 30a of the detachable transparent coupler 30 protruding out of the first substrate 12, 22 may be greater than or less than 5.0 mm. With the design of the portion 30a of the detachable transparent coupler 30 protruding out of at least one of the first substrate 12, 22 and the second substrate 14, 24, the display device 1 according to the present disclosure may, during the reworking operation, improve the convenience of disassembling the transparent display units 10 and 20 by gripping or clamping the protruding portion 30a.

In one embodiment, as shown in FIGS. 1A and 1C, in an overlapping regions of the first substrate 12, 22 and the second substrate 14, 24, the dimension of the display component 16, 26 is preferably less than the dimensions of the first substrate 12, 22 and the second substrate 14, 24, such that the transparent display units 10 and 20 respectively form gap regions 15 and 25 surrounding the display components 16 and 26 between the first substrates 12 and 22 and the second substrates 14 and 24. The gap regions 15 and 25 are preferably provided along the periphery of the transparent display units 10 and 20, thus forming the gap regions 15 and 25 in a “Π” shape. In other words, the gap regions 15 and 25 are provided on sides other than the first side 1a, such as the second side 1b and the two sides adjacent to the second side 1b. The portions of the gap regions 15 and 25 located on the adjacent sides of the two transparent display units 10 and 20 serve as an accommodating space for the detachable transparent coupler 30, and the remaining portions of the gap regions 15 and 25 may serve as the filling spaces for subsequently filling the colloidal adhesive, such that the display device 1 may form a wide “II”-shaped colloidal adhesive 70 (as shown in FIG. 3E and described later in details) with approximately twice the width in the gap regions 15 and 25.

The detachable transparent coupler 30 is preferably pre-manufactured using materials with a hardness slightly lower than that of the first substrates 12 and 22 and the second substrates 14 and 24, through methods such as molding or injection molding. For example, the materials of the detachable transparent coupler 30 may include rubber, polymethyl methacrylate (PMMA), polycarbonate (PC), polystyrene (PS) or polyethylene terephthalate (PET), but is not limited thereto. The transparency of the detachable transparent coupler 30 is preferably 80% or higher, and the reflectivity (SCI) of the detachable transparent coupler 30 is preferably 5% or less. In addition, the deformation temperature and melting temperature of the detachable transparent coupler 30 are preferably 90° C. or higher and 150° C. or higher, respectively. Any material that provides with these properties may be used for manufacturing the detachable transparent coupler 30.

As shown in FIGS. 1A to 1C, in the present embodiment, the detachable transparent coupler 30 may have a position limiting portion 32. The position limiting portion 32 is preferably disposed along a length direction of the detachable transparent coupler 30 and protrudes from the detachable transparent coupler 30. Specifically, the detachable transparent coupler 30 has a flat strip-shaped body extending along the adjacent side edges of the two transparent display units 10 and 20. The position limiting portion 32 preferably extends perpendicularly outward from the surface of the flat strip-shaped body, thus dividing the flat strip-shaped body of the detachable transparent coupler 30 into wing portions 34a and 34b along the length direction of the detachable transparent coupler 30. When the detachable transparent coupler 30 is assembled between the two transparent display units 10 and 20, the wing portions 34a and 34b are inserted into the adjacent gap regions 15 and 25 of the two transparent display units 10 and 20, respectively, such that the adjacent side edges of the two transparent display units contact the two opposite sides of the position limiting portion 32. In the present embodiment, the position limiting portion 32 may be disposed positioned on the two opposite surfaces of the detachable transparent coupler 30, such that the detachable transparent coupler has a “+”-shaped cross-section. When the detachable transparent coupler 30 is assembled between the two transparent display units 10 and 20, the first substrates 12 and 22 may contact, for example, the two opposite sides of the position limiting portion 32 on the upper surface, and the second substrates 14 and 24 may contact the two opposite sides of the position limiting portion 32 on the lower surface, without being limited thereto. In another embodiment, the detachable transparent coupler 30 may have a T-shaped cross-section, such that only one of the first substrate 12, 22 and the second substrate 14, 24 (e.g., the first substrates 12 and 22) contacts the two opposite sides of the position limiting portion 32, while the others of the first substrate 12, 22 and the second substrate 14, 24 (e.g., the second substrates 14 and 24) form a gap between them. In yet another embodiment, the detachable transparent coupler 30 may have a “−”-shaped cross-section (that is, the detachable transparent coupler 30 does not have a position limiting portion 32), such that the first substrates 12 and 22 may either contact each other or remain separated, and the second substrates 14 and 24 may similarly either contact each other or remain separated.

In one embodiment, as shown in FIG. 1C, the thickness T of the transparent display units 10 and 20 (i.e., the distance from the outer surface of the first substrate 12, 22 to the outer surface of the second substrate 14, 24) may be about 3.9 mm. The distance D1 or D2 from the display component 16, 26 to the edge of the first substrate 12, 22 (or the second substrate 14, 24) of the transparent display unit 10, 20 (i.e., the width of the gap region 15, 25 in the horizontal direction) may be about 3.0 mm. The distance D3 between the two transparent display units 10 and 20 may be about 1.0 mm. The distance D4 from the display component 16 to the edge of the optical adhesive 18 may be about 0.3 mm. The distance D5 between the first substrate 12, 22 and the second substrate 14, 24 of the transparent display unit 10, 20 (i.e., the thickness of the gap region 15, 25) may be about 1.3 mm. According to the actual applications, the thicknesses or distances may vary without being limited to the values provided. From another perspective, the dimension of the position limiting portion 32 of the detachable transparent coupler 30 in the short-axis (width) direction substantially defines the distance D3 between the two transparent display units 10 and 20, and the protrusion height (i.e., thickness) of the position limiting portion 32 preferably corresponds to the top surfaces of the first substrates 12 and 22, such that the position limiting portion 32 and the first substrates 12 and 22 are substantially coplanar after assembly. The dimensions of the wing portions 34a and 34b in the short-axis (width) direction are preferably less than the distance between the edge of the optical adhesive 18, 28 and the first substrate 12, 22 (or the second substrate 14, 24), such as D1 (or D2) minus D4. The dimensions of the wing portions 34a and 34b in the thickness direction are preferably equal to or slightly greater than the distance D5 between the first substrate 12, 22 and the second substrate 14, 24, such that the wing portions 34a and 34b of the detachable transparent coupler 30 may respectively press fit in the gap regions 15 and 25.

Referring to FIG. 2, FIG. 2 is a partial plain schematic view of a second side (e.g., 1b) of a display device (e.g., the display device 1) according to one embodiment of the present disclosure. As shown in FIG. 2, at the second side 1b of the display device 1, the detachable transparent coupler 30 is recessed inward relative to the two transparent display units 10 and 20, thus forming an adhesive space SP between the two transparent display units 10 and 20 and the detachable transparent coupler 30. In one embodiment, the corners of the transparent display units 10 and 20 may be chamfered in rounded shapes to enlarge the dimension of the adhesive space SP and increase the filling margin, without being limited thereto. In other embodiments, the corners of the transparent display units 10 and 20 may be in right-angles or beveled forms. In one embodiment, the recessed distance G of the detachable transparent coupler 30 (i.e., the distance between the detachable transparent coupler 30 and the edge of the display device 1 at the second side 1b) is preferably 1.0 mm or more and 5.0 mm or less, without being limited thereto. The recessed distance G of the detachable transparent coupler 30 may vary according to the properties of the colloidal adhesive (e.g., adhesiveness, flowability, etc.) and the manufacturing process of coating the colloidal adhesive.

In another embodiment of the present disclosure, a manufacturing method of the display device 1 is also provided. Referring to FIGS. 1A and 1B, the manufacturing method of the display device 1 includes: providing two transparent display units 10 and 20, where each of the transparent display units 10 and 20 includes a first substrate 12, 22, a second substrate 14, 24 and a display component 16, 26 disposed between the first substrate 12, 22 and the second substrate 14, 24; and assembling a detachable transparent coupler 30 between the two transparent display units 10 and 20, such that at a first side 1a of the display device 1, a portion 30a of the detachable transparent coupler 30 protrudes from at least one of the first substrate 12, 22 and the second substrate 14, 24 of one of the two transparent display units 10 and 20.

Referring to FIG. 2, the step of assembling the detachable transparent coupler 30 between the two transparent display units 10 and 20 may include: at a second side 1b of the display device 1, recessing the detachable transparent coupler 30 inward relative to the two transparent display units 10 and 20 to form an adhesive space SP between the two transparent display units 10 and 20 and the detachable transparent coupler 30.

Moreover, in one embodiment, as shown in FIG. 3A to FIG. 3E, the display device 1 may further include a base 40, a circuit board 50, a cover 60 and the colloidal adhesive 70. The details of the base 40, the circuit board 50, the cover 60 and the colloidal adhesive 70 and the corresponding manufacturing method of the display device 1 are hereinafter described with respect to FIGS. 3A to 3E.

As shown in FIG. 3A to FIG. 3C, the display device 1 further includes the base 40. The base 40 is used to integrate the components of the display device 1, such that combined with the cover 60, the display device 1 has an integral and streamlined appearance. In the present embodiment, the step of assembling the detachable transparent coupler 30 between the two transparent display units 10 and 20 may include: disposing one of the two transparent display units 10 and 20 on the base 40; inserting a portion of the detachable transparent coupler 30 into a side of the one of the two transparent display units 10 and 20; and disposing the other of the two transparent display units 10 and 20 on the base 40, and inserting another portion of the detachable transparent coupler 30 into a side of the other of the two transparent display units 10 and 20.

Specifically, as shown in FIG. 3A, in the present embodiment, the transparent display unit 10 is partially disposed on the base 40, such that one side of the transparent display unit 10 having the electrical connecting portion 162 is disposed above the base 40. In one embodiment, the base 40 may have a receiving slot 42 to receive and position the transparent display units 10 and 20 and the detachable transparent coupler 30. For example, when the transparent display unit 10 is disposed on the base 40, the left side of the transparent display unit 10 may abut against the left side of the receiving slot 42, thus achieving the positioning of the transparent display unit 10 in the horizontal direction. In addition, the lower edge of the second substrate 14 of the transparent display unit 10 may abut against the wall surface of the receiving slot 42 extending along the horizontal direction, thus achieving the positioning of the transparent display unit 10 in the vertical direction. Then, the detachable transparent coupler 30 moves from the right side of the transparent display unit 10 toward the left side thereof to engage the wing portion 34a of the detachable transparent coupler 30 into the gap region 15 between the first substrate 12 and the second substrate 14 of the transparent display unit 10 at the right side, thus completing the assembling stage as shown in the left side of FIG. 3B. In this assembling stage, the lower edge of the detachable transparent coupler 30 preferably abuts against the wall surface of the receiving slot 42 extending along the horizontal direction, thus achieving the positioning of the detachable transparent coupler 30 in the vertical direction. In other words, with the design of the length of the detachable transparent coupler 30, the arrangement may define the recessed distance G of the detachable transparent coupler 30 at the second side 1b of the display device 1. As shown in FIG. 3B, the transparent display unit 20 moves from the right side of the detachable transparent coupler 30 toward the left side thereof to engage the wing portion 34b of the detachable transparent coupler 30 into the gap region 25 between the first substrate 22 and the second substrate 24 of the transparent display unit 20 at the left side, thus completing the assembling stage as shown in the upper side of FIG. 3C. In this assembling stage, the two transparent display units 10 and 20 and the detachable transparent coupler 30 are partially disposed at a side of the base 40 in a combined manner, and the portion 30a of the detachable transparent coupler 30 protruding from the first substrates 12 and 22 is adjacent to the base 40 and overlays on the base 40. Moreover, the adhesive space SP as shown in FIG. 2 may be defined at the second side 1b of the display device 1.

As shown in FIGS. 3C and 3D, the display device 1 further includes the circuit board 50. The circuit board 50 is disposed in the base 40 and is electrically connected to the two transparent display units 10 and 20. Specifically, the circuit board 50 is electrically connected to the electrical connecting portions 162 and 262 of the display components 16 and 26, thus achieving the electrical control of the display device 1 to the transparent display units 10 and 20. Referring to FIG. 3C, the manufacturing method of the display device 1 further includes a step of disposing a circuit board 50 in the base 40, such that the circuit board 50 is electrically connected to the two transparent display units 10 and 20.

As shown in FIGS. 3D and 3E, the display device 1 further includes the cover 60, and the cover 60 is preferably combined with the base 40. For example, the cover 60 may be fixed to the base 40 by screws or a clamping mechanism. The cover 60 is disposed at the first side 1a of the display device 1 and covers the circuit board 50. Preferably, the cover 60 further partially covers the first substrates 12 and 22 to enhance the aesthetic appearance of the display device 1. Referring to FIG. 3D, the manufacturing method of the display device 1 further includes a step of disposing a cover 60 to be combined with the base 40.

As shown in FIG. 3E, the display device 1 further includes a colloidal adhesive 70, which is preferably transparent. The material of the colloidal adhesive 70 may include epoxy, latex, polyvinyl alcohol (PVA), etc. The colloidal adhesive 70 is disposed along edges of the two transparent display units 10 and 20, and the colloidal adhesive 70 is not disposed at the first side 1a of the display device 1. For example, the colloidal adhesive 70 is coated along the left side, the second side 1b and the right side of the display device 1, such that the colloidal adhesive 60 has a wide “Π” shape with approximately twice the width of the transparent display units 10 and 20. In one embodiment, the colloidal adhesive 60 is preferably located between the first substrate 12, 22 and the second substrate 14, 24 of each of the two transparent display units 10 and 20. For example, an adhesive material is coated along the gap region 15 at the left side and the upper side of the transparent display unit 10, the adhesive space SP and the gap region 25 at the upper side and the right side of the transparent display unit 20, and the adhesive material is cured to form the colloidal adhesive 60. In one embodiment, the colloidal adhesive 60 is preferably fully located in the gap region 15 and the gap region 25, without being limited thereto. In another embodiment, the colloidal adhesive 60 may slightly overflow from the gap regions 15 and 25 of the transparent display units 10 and 20. The colloidal adhesive 70 may improve the waterproof, dustproof, protection, aesthetics and other effects of the display device 1.

Referring to FIG. 3E, the manufacturing method of the display device 1 may further include disposing a colloidal adhesive 70 along edges of the two transparent display units 10 and 20, and the colloidal adhesive 70 is not disposed at the first side 1a of the display device 1. Moreover, the step of disposing the colloidal adhesive 70 includes: disposing the colloidal adhesive 70 in the adhesive space SP.

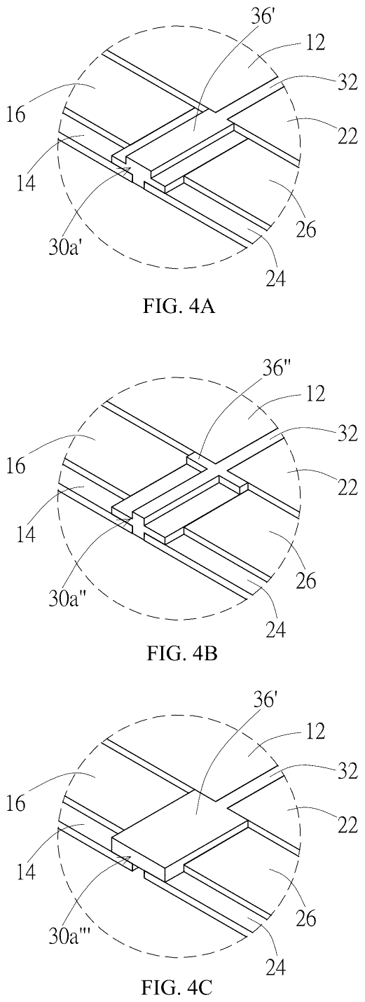

In the aforementioned embodiments, the detachable transparent coupler 30 achieves positioning in the vertical direction by abutting against the receiving slot 42 of the base 40, without being limited thereto. In other embodiments, the detachable transparent coupler 30 may have a positioning portion, and the positioning in the vertical direction may be achieved by the positioning portion abutting against the base. FIGS. 4A to 4C are schematic views of the positioning portion 36′, 36″ and 36′″ of the detachable transparent coupler according to different embodiments of the present disclosure, which are partially enlarged views corresponding to the region A of FIG. 1B. As shown in FIG. 4A, the detachable transparent coupler 30 has the positioning portion 36′. The positioning portion 36′ is disposed on the portion 30a′ of the detachable transparent coupler 30 protruding from the first substrates 12 and 22, and the positioning portion 36′ protrudes from the detachable transparent coupler 30 to contact a side edge of the at least one of the first substrate 12, 22 and the second substrate 14, 24 of the one of the two transparent display units 10 and 20. For example, the positioning portion 36′ extends from the position limiting portion 32, and a width of the positioning portion 36′ is greater than a width of the position limiting portion 32. During assembly, the lower-right side of the first substrate 12 and the lower-left side of the second substrate 22 may respectively abut against the positioning portion 36′, thus achieving positioning of the transparent display units 10 and 20 in the vertical direction. In the present embodiment, the positioning portion 36′ is a strip-shaped protruding portion disposed along the vertical (or length) direction, without being limited thereto. In another embodiment, as shown in FIG. 4B, the positioning portion 36″ is disposed on the portion 30a″ of the detachable transparent coupler 30 protruding from the first substrates 12 and 22, and the positioning portion 36″ is a strip-shaped protruding portion disposed along the horizontal (or width) direction. In yet another embodiment, as shown in FIG. 4C, the positioning portion 36′″ is disposed on the portion 30a′″ of the detachable transparent coupler 30 protruding from the first substrates 12 and 22, and the positioning portion 36′″ is a block-shaped protruding portion.

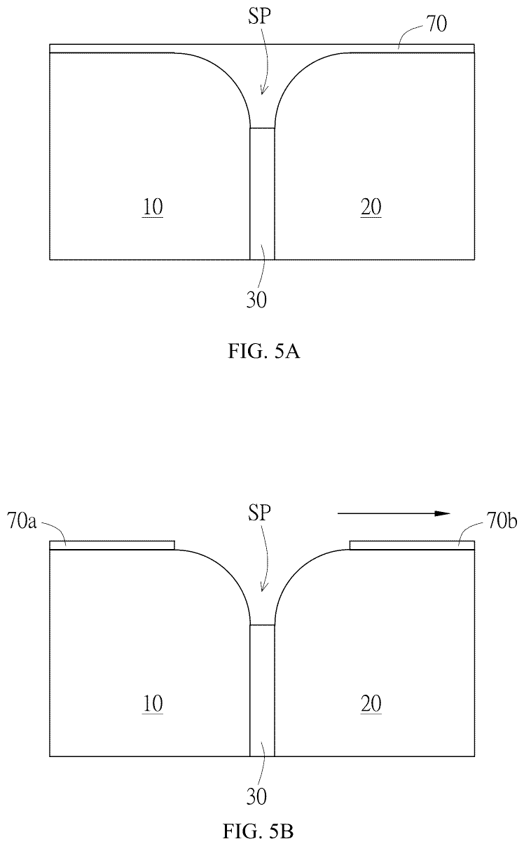

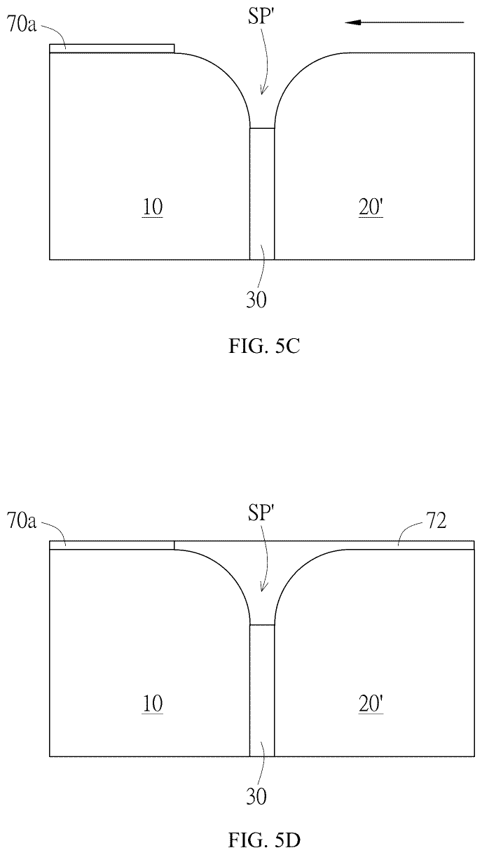

Moreover, the manufacturing method of the display device 1 further includes a reworking step. The reworking step may be applied by a reverse application of the assembling steps with reference to FIGS. 3A to 3E, such as sequentially removing the cover 60 and the circuit board 50, and is thus not hereinafter reiterated. The following description focuses on the disassembling of the two transparent display units 10 and 20 and the detachable transparent coupler 30. Referring to FIGS. 5A to 5D, which are partial plain schematic views similar to the second side 1b of the display device 1 of FIG. 2. For convenience of illustration, the colloidal adhesive 70 is exaggerated to be shown as protruding from the transparent display units 10 and 20. In practice, the colloidal adhesive 70 may be fully located within the gap regions 15 and 25 of the transparent display units 10 and 20, or may slightly overflow from the gap regions 15 and 25 of the transparent display units 10 and 20. As shown in FIG. 5A, the colloidal adhesive 70 is disposed along the side edge of the transparent display unit 10, filling the adhesive space SP, and is also disposed along the side edge of the transparent display unit 20, thereby adhering the two transparent display units 10 and 20 together through the colloidal adhesive 70 in the adhesive space SP.

As shown in FIG. 5B, the reworking step includes: at the second side 1b of the display device 1, removing a portion of the colloidal adhesive 70 to at least expose the adhesive space SP. Specifically, in this step, the colloidal adhesive 70 in the adhesive space SP is removed, such that the two transparent display units 10 and 20 at the second side 1b of the display device 1 do not have portions being adhered by the colloidal adhesive 70. In this case, unremoved portions 70a and 70b of the colloidal adhesive respectively remain on the two transparent display units 10 and 20.

Moreover, the reworking step includes: disassembling one of the two transparent display units 10 and 20 to be reworked from the detachable transparent coupler 30. Specifically, since the two transparent display units 10 and 20 at the second side 1b of the display device 1 do not have portions being adhered by the colloidal adhesive 60, the one to be reworked may be easily disassembled from the detachable transparent coupler 30. For example, as shown in FIG. 5B, if the transparent display unit 20 is damaged or has defects, the transparent display unit 20 moves outward (e.g., toward the right side) such that the transparent display unit 20 detaches from the right side of the detachable transparent coupler 30. Similarly, if the transparent display unit 10 is damaged or has defects, the transparent display unit 10 moves outward (e.g., toward the left side) such that the transparent display unit 10 detaches from the left side of the detachable transparent coupler 30.

As shown in FIG. 5C, the reworking step includes: assembling a replacement transparent display unit 20′ in the detachable transparent coupler 30. In the present embodiment, the transparent display unit 20′ may have identical structures to those of the transparent display units 10 and 20, without being limited thereto. For example, if the transparent display unit 20′ replaces the transparent display unit 20, the transparent display unit 20′ moves from the right side of the detachable transparent coupler 30 toward the left side thereof, such that the portion of the detachable transparent coupler 30 (e.g., the wing portion 34b in the aforementioned embodiment) is engaged into the gap region between the two substrates of the transparent display unit 20′ at the left side. If the transparent display unit 20′ replaces the transparent display unit 10, the transparent display unit 20′ moves from the left side of the detachable transparent coupler 30 toward the right side thereof, such that the portion of the detachable transparent coupler 30 (e.g., the wing portion 34a in the aforementioned embodiment) is engaged into the gap region between the two substrates of the transparent display unit 20′ at the right side. Thus, the adhesive space SP′ is formed between the transparent display unit 10 or 20 (the transparent display unit 10 in the present embodiment), the transparent display unit 20′ and the detachable transparent coupler 30.

As shown in FIG. 5D, the reworking step includes: coating a reworking colloidal adhesive 72 along edges of the replacement transparent display unit 20′, where the reworking colloidal adhesive 72 is filled in the adhesive space SP′ and is connected to an unremoved portion (e.g., 70a) of the colloidal adhesive. For example, if the transparent display unit 20′ replaces the transparent display unit 20, the reworking colloidal adhesive 72 is coated along the gap region at the right side and the upper side of the transparent display unit 20′, and the reworking colloidal adhesive 72 is filled in the adhesive space SP′, such that the reworking colloidal adhesive 72 is connected to the unremoved portion 70a of the colloidal adhesive on the transparent display unit 10 in the previous step. If the transparent display unit 20′ replaces the transparent display unit 10, the reworking colloidal adhesive 72 is coated along the gap region at the left side and the upper side of the transparent display unit 20′, and the reworking colloidal adhesive 72 is filled in the adhesive space SP′, such that the reworking colloidal adhesive 72 is connected to the unremoved portion 70b of the colloidal adhesive on the transparent display unit 20 in the previous step. After the completion of the reworking operation, the unremoved portion (e.g., 70a or 70b) of the colloidal adhesive and the reworking colloidal adhesive 72 form a connecting interface observable by naked eyes or instruments. The reworking colloidal adhesive 72 may use materials identical to or different from the materials of the colloidal adhesive 70, which may include, for example, epoxy, latex, polyvinyl alcohol (PVA), etc.

The manufacturing method of the display device 1 according to the present disclosure may further include a disassembling step, which includes: at the second side 1b of the display device 1, removing a portion of the colloidal adhesive 70 to at least expose the adhesive space SP, such that the two transparent display units 10 and 20 at the second side 1b of the display device 1 do not have portions being adhered by the colloidal adhesive 70 (the details thereof may refer to the reworking step as described above, and are thus not hereinafter reiterated); disassembling one of the two transparent display units 10 and 20 from the detachable transparent coupler 30 (e.g., disassembling the transparent display unit 20 outward from the right side thereof); and disassembling the other of the two transparent display units 10 and 20 from the detachable transparent coupler 30 (e.g., disassembling the transparent display unit 10 outward from the left side thereof). Specifically, the steps of disassembling the two transparent display units 10 and 20 may be performed by gripping or clamping the protruding portion 30a of the detachable transparent coupler 30 protruding out of the first substrate 12, 22 and the second substrate 14, 24, and applying a force from the first side 1a of the display device 1 toward the second side 1b to gradually detach the detachable transparent coupler 30 and the transparent display units 10 and 20.

In the display device 1 and the manufacturing method thereof according to the present disclosure, the transparent display units 10 and 20 are assembled by the detachable coupler 30, thus effectively improving the convenience of splicing and detaching of the display device 1. Moreover, in the display device 1 and the manufacturing method thereof according to the present disclosure, the transparent display units 10 and 20 are assembled by the detachable coupler 30, thus effectively reducing the colloidal adhesive used for adhering between the transparent display units 10 and 20, enhancing the convenience of the reworking operation or the disassembling operation, and reducing the possibility of damaging the transparent display units 10 and 20, thereby enhancing the reusability of the detachable coupler 30 and the transparent display units 10 and 20, and achieving the effects of a circular economy.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A display device, comprising:
two transparent display units, wherein each of the transparent display units comprises a first substrate, a second substrate and a display component disposed between the first substrate and the second substrate; and
a detachable transparent coupler, assembled between the two transparent display units,
wherein at a first side of the display device, a portion of the detachable transparent coupler protrudes from at least one of the first substrate and the second substrate of one of the two transparent display units.

2. The display device according to claim 1, further comprising a colloidal adhesive disposed along edges of the two transparent display units, wherein the colloidal adhesive is not disposed at the first side of the display device.

3. The display device according to claim 2, wherein at a second side of the display device opposite to the first side, the detachable transparent coupler is recessed inward relative to the two transparent display units to form an adhesive space between the two transparent display units and the detachable transparent coupler, and the adhesive space is filled with the colloidal adhesive.

4. The display device according to claim 2, wherein the colloidal adhesive is located between the first substrate and the second substrate of each of the two transparent display units.

5. The display device according to claim 1, wherein at the first side of the display device, the first substrate of the one of the two transparent display units is recessed relative to the second substrate thereof, and the portion of the detachable transparent coupler protrudes to the recessed first substrate.

6. The display device according to claim 1, wherein the detachable transparent coupler has a positioning portion, the positioning portion is disposed on the portion of the detachable transparent coupler and protrudes from the detachable transparent coupler to contact a side edge of the at least one of the first substrate and the second substrate of the one of the two transparent display units.

7. The display device according to claim 1, wherein the detachable transparent coupler has a position limiting portion, the position limiting portion is disposed along a length direction of the detachable transparent coupler and protrudes from the detachable transparent coupler, and adjacent side edges of the two transparent display units respectively contact two opposite sides of the position limiting portion.

8. The display device according to claim 1, wherein transparency of the detachable transparent coupler is 80% or higher.

9. The display device according to claim 1, wherein reflectivity of the detachable transparent coupler is 5% or less.

10. The display device according to claim 1, further comprising a base, wherein the two transparent display units and the detachable transparent coupler are disposed at a side of the base, and the portion of the detachable transparent coupler is adjacent to the base.

11. The display device according to claim 10, further comprising a circuit board disposed in the base and electrically connected to the two transparent display units.

12. A manufacturing method of a display device, comprising:
providing two transparent display units, wherein each of the transparent display units comprises a first substrate, a second substrate and a display component disposed between the first substrate and the second substrate; and
assembling a detachable transparent coupler between the two transparent display units, such that at a first side of the display device, a portion of the detachable transparent coupler protrudes from at least one of the first substrate and the second substrate of one of the two transparent display units.

13. The manufacturing method according to claim 12, further comprising disposing a colloidal adhesive along edges of the two transparent display units, wherein the colloidal adhesive is not disposed at the first side of the display device.

14. The manufacturing method according to claim 13, wherein:
the step of assembling the detachable transparent coupler between the two transparent display units comprises: at a second side of the display device opposite to the first side, recessing the detachable transparent coupler inward relative to the two transparent display units to form an adhesive space between the two transparent display units and the detachable transparent coupler; and
the step of disposing the colloidal adhesive comprises: disposing the colloidal adhesive in the adhesive space.

15. The manufacturing method according to claim 12, wherein the step of assembling the detachable transparent coupler between the two transparent display units comprises:
disposing one of the two transparent display units on the base;
inserting a portion of the detachable transparent coupler into a side of the one of the two transparent display units; and
disposing the other of the two transparent display units on the base, and inserting another portion of the detachable transparent coupler into a side of the other of the two transparent display units.

16. The manufacturing method according to claim 15, further comprising disposing a circuit board in the base, such that the circuit board is electrically connected to the two transparent display units.

17. The manufacturing method according to claim 14, further comprising a reworking step, wherein the reworking step comprises:
at the second side of the display device, removing a portion of the colloidal adhesive to at least expose the adhesive space;
disassembling one of the two transparent display units to be reworked from the detachable transparent coupler;
assembling a replacement transparent display unit in the detachable transparent coupler; and
coating a reworking colloidal adhesive along edges of the replacement transparent display unit, wherein the reworking colloidal adhesive is filled in the adhesive space and is connected to an unremoved portion of the colloidal adhesive.
